(19) United States
(12) Patent Application Publication
(10) Pub. No.: US 2024/0365536 A1
(43) Pub. Date: Oct. 31, 2024

(54) SEMICONDUCTOR DEVICE HAVING CONTACT PLUG CONNECTED TO WORD LINE

(71) Applicant: MICRON TECHNOLOGY, INC., BOISE, ID (US)

(72) Inventor: RIHO KAWANO, Higashihiroshima (JP)

(73) Assignee: MICRON TECHNOLOGY, INC., Boise, ID (US)

(21) Appl. No.: 18/623,661

(22) Filed: Apr. 1, 2024

Related U.S. Application Data
(60) Provisional application No. 63/498,408, filed on Apr. 26, 2023.

(51) Int. Cl. H10B 12/00

(52) U.S. Cl. CPC H10B 12/488; H10B 12/09; H10B 12/50

(57) ABSTRACT

An apparatus that includes a semiconductor substrate in a first layer, the semiconductor substrate being divided, at least in part, into a memory cell array region, a peripheral circuit region and a contact plug region between the memory cell array region and the peripheral circuit region; a plurality of word lines embedded in the semiconductor substrate and extending in parallel across the memory cell array region and the contact plug region; a nitride film in a second layer above the first layer, the nitride film covering the memory cell array region and the contact plug region; an oxide film in the second layer, the oxide film covering the peripheral circuit region; and a plurality of contact plugs in the nitride film above the contact plug region to be connected to the plurality of word lines, respectively.

### CROSS-REFERENCE TO RELATED APPLICATIONS

This application claims priority to U.S. Provisional Application No. 63/498,408, filed Apr. 26, 2023. The aforementioned application is incorporated herein by reference, in its entirety, for any purpose.

### BACKGROUND

Word lines used in a semiconductor memory device such as a DRAM (Dynamic Random Access Memory) are embedded in a semiconductor substrate and an STI (Shallow Trench Isolation) region in some cases. These embedded word lines are connected to a word driver via associated contact plugs provided through an interlayer dielectric film, respectively. If the arrangement pitch of the word lines is narrow in this situation, there is a risk of a short circuit failure occurring between adjacent ones of the contact plugs.

### BRIEF DESCRIPTION OF THE DRAWINGS

FIG. 1A is a schematic plan view showing a part of a peripheral circuit region of a semiconductor memory device according to one embodiment of the present disclosure and FIG. 1B is a schematic cross-sectional view along a line B-B shown in FIG. 1A;

FIG. 1C is a schematic plan view showing a part of a memory cell array region of the semiconductor memory device according to one embodiment of the present disclosure, FIG. 1D is a schematic cross-sectional view along a line D-D shown in FIG. 1C, and FIG. 1E is a schematic cross-sectional view along a line E-E shown in FIG. 1C;

FIGS. 2A, 3A, 4A, 5A, 6A, 7A, 8A, 9A, 10A, and 11A are process diagrams for explaining a manufacturing method of a semiconductor memory device according to one embodiment of the present disclosure and correspond to a region shown in FIG. 1A;

FIGS. 2B, 3B, 4B, 5B, 6B, 7B, 8B, 9B, 10B, and 11B are schematic cross-sectional views along a line B-B shown in FIGS. 2A, 3A, 4A, 5A, 6A, 7A, 8A, 9A, 10A, and 11A, respectively;

FIGS. 2C, 3C, 4C, 5C, 6C, 7C, 8C, 9C, 10C, and 11C are process diagrams for explaining the manufacturing method of a semiconductor memory device according to one embodiment of the present disclosure and correspond to a region shown in FIG. 1C;

FIGS. 2D, 3D, 4D, 5D, 6D, 7D, 8D, 9D, 10D, and 11D are schematic cross-sectional views along a line D-D shown in FIGS. 2C, 3C, 4C, 5C, 6C, 7C, 8C, 9C, 10C, and 11C, respectively; and

FIGS. 2E, 3E, 4E, 5E, 6E, 7E, 8E, 9E, 10E, and 11E are schematic cross-sectional views along a line E-E shown in FIGS. 2C, 3C, 4C, 5C, 6C, 7C, 8C, 9C, 10C, and 11C, respectively.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

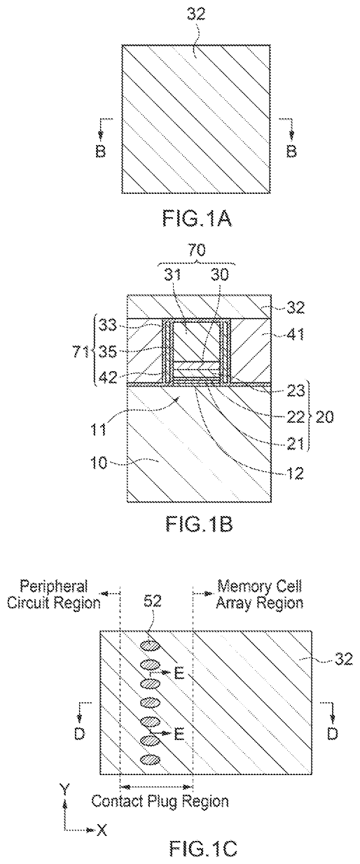

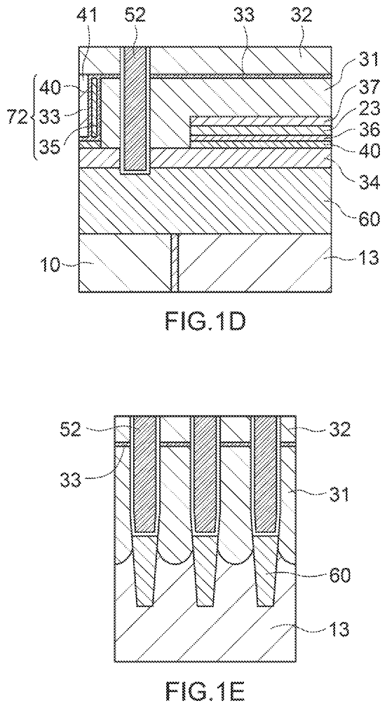

FIG. 1A is a schematic plan view showing a part of a peripheral circuit region of a semiconductor memory device according to one embodiment of the present disclosure. FIG. 1B is a schematic cross-sectional view along a line B-B shown in FIG. 1A. FIG. 1C is a schematic plan view showing a part of a memory cell array region of the semiconductor memory device according to one embodiment of the present disclosure. FIG. 1D is a schematic cross-sectional view along a line D-D shown in FIG. 1C. FIG. 1E is a schematic cross-sectional view along a line E-E shown in FIG. 1C.

The semiconductor memory device according to the present embodiment is, for example, a DRAM and a silicon substrate 10 constituting a first layer has the memory cell array region and the peripheral circuit region as shown in FIG. 1C. A plurality of memory cells, and a plurality of word lines and a plurality of bit lines respectively connected to the memory cells are arranged in the memory cell array region. A plurality of word lines 60 embedded in the silicon substrate 10 and an STI region 13 are shown in FIGS. 1D and 1E. The word lines 60 extend in an X direction and are arrayed in a Y direction. In some examples, the X direction and the Y direction may be perpendicular to one another. Transistors constituting peripheral circuits such as a decoder circuit and a control circuit are arranged in the peripheral circuit region. A transistor 11 arranged in the peripheral circuit region is shown in FIG. 1B. The transistor 11 includes a source region, a drain region, and a channel region formed in the silicon substrate 10, a gate dielectric film 12 covering the channel region, and a gate electrode 20 provided on the gate dielectric film 12. The gate electrode 20 has a structure in which a titanium nitride film 21, a polysilicon film 22, and a tungsten film 23 are stacked in this order. The top surface of the gate electrode 20 is covered with a gate cap dielectric film 70 including silicon nitride films 30 and 31. A sidewall dielectric film 71 is provided between side surfaces of the gate electrode 20 and the gate cap dielectric film 70, and a silicon oxide film 41. The sidewall dielectric film 71 includes a silicon nitride film 33, a silicon oxide film 42, and a silicon nitride film 35. The silicon nitride film 33 is formed also on the top surface of the gate cap dielectric film 70. The gate gap dielectric film 70 and the silicon oxide film 41 are covered with a silicon nitride film 32. The silicon nitride film 31 and the silicon oxide film 41 constitute a second layer on the silicon substrate 10. While it is permissible that an insulating film other than a silicon nitride film is included in the second layer on a contact plug region, at least half or a larger part of the second layer is constituted by the silicon nitride film 31. While it is permissible that an insulating film other than a silicon oxide film is included in the second layer on the peripheral circuit region, at least half or a larger part of the second layer is constituted by the silicon oxide film 41.

The contact plug region including a plurality of contact plugs 52 is arranged between the memory cell array region and the peripheral circuit region. The contact plugs 52 are arrayed in the Y direction and are connected to end portions of associated word lines 60, respectively. The contact plugs 52 are provided to penetrate through the silicon nitride films 31 to 33 and a silicon nitride film 34. Accordingly, a lower section of each of the contact plugs 52 connected to the associated one of the word lines 60 is surrounded by the silicon nitride film 31 and an upper section of each of the contact plugs 52 is surrounded by the silicon nitride film 32. As shown in FIG. 1D, a part of the lower section of each of the contact plugs 52 is sandwiched by the silicon nitride film 34 in the X direction. As shown in FIG. 1E, an upper section of each of the word lines 60 connected to the associated one of the contact plugs 52 is sandwiched by the silicon nitride film 31 in the Y direction and a lower section of each of the word lines 60 is sandwiched by the STI region 13 in the Y direction.

As shown in FIG. 1D, a sidewall dielectric film 72 remains at a boundary location between the peripheral circuit region and the contact plug region. The sidewall dielectric film 72 has the same structure as that of the sidewall dielectric film 71 covering the gate electrode 20. This sidewall dielectric film 72 is not formed at a boundary location between the memory cell array region and the contact plug region. That is, the silicon nitride film 31 is continuously located across the memory cell array region and the contact plug region. The tungsten film 23 constituting the bit lines is located in the memory cell array region. A silicon nitride film 36 is located between the tungsten film 23 and the silicon oxide film 40 and a silicon nitride film 37 is located between the tungsten film 23 and the silicon nitride film 31.

A manufacturing process of the semiconductor memory device according to the present embodiment is explained next.

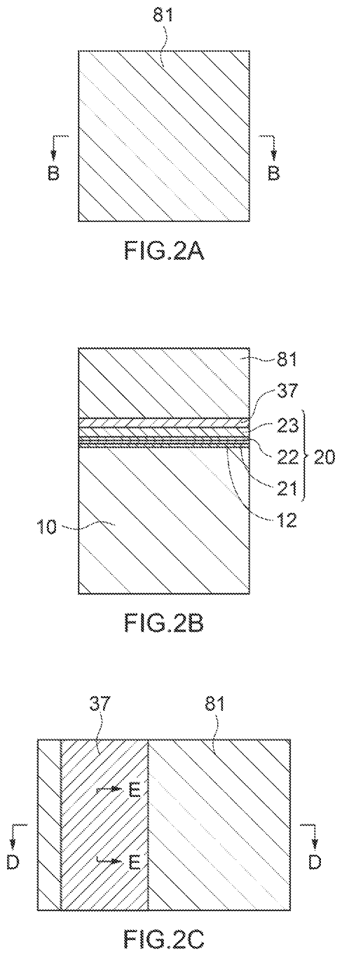

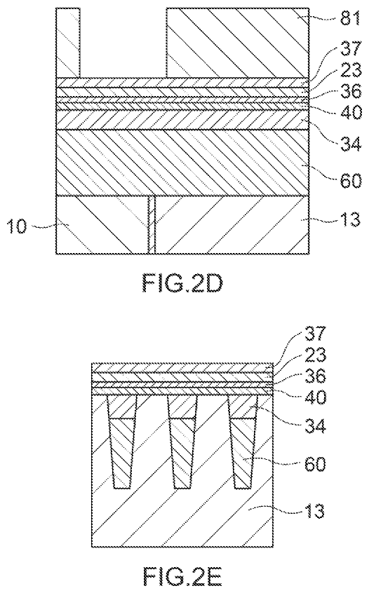

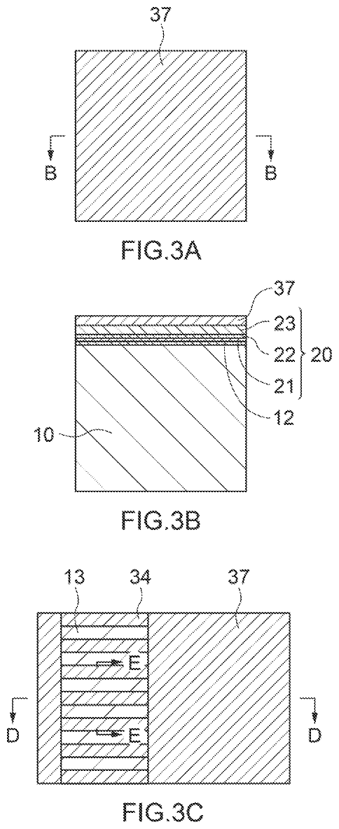

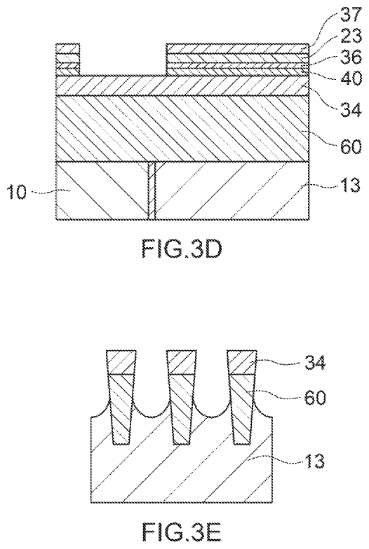

First, as shown in FIGS. 2A to 2E, after a plurality of the word lines 60 are formed in the memory cell array region, the silicon nitride film 34, the silicon oxide film 40, the silicon nitride film 36, the tungsten film 23, and the silicon nitride film 37 are deposited in this order to cover the word lines 60. In the peripheral circuit region, the titanium nitride film 21 and the polysilicon film 22 are formed between the gate dielectric film 12 and the tungsten film 23. Next, after a resist 81 is formed on the whole surface, the resist 81 is patterned to remove the resist 81 covering the contact plug region. The memory cell array region and the peripheral circuit region are in a state of being covered with the resist 81. In this state, the silicon nitride film 37, the tungsten film 23, the silicon nitride film 36, the silicon oxide film 40, and the STI region 13 are etched using the resist 81 as a mask as shown in FIGS. 3A to 3E. Accordingly, in the contact plug region, the upper sections of the word lines 60 and the silicon nitride film 34 on the word lines 60 are exposed and a part of the STI region 13 is removed. The STI region 13 is exposed between the word lines 60 adjacent in the Y direction.

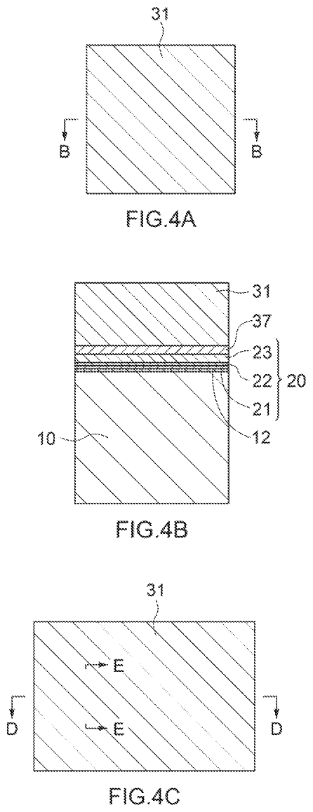

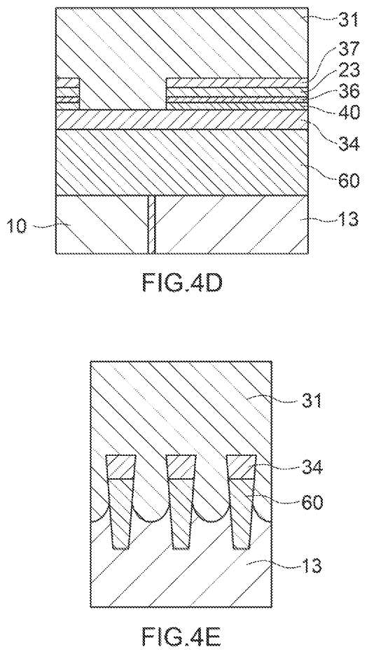

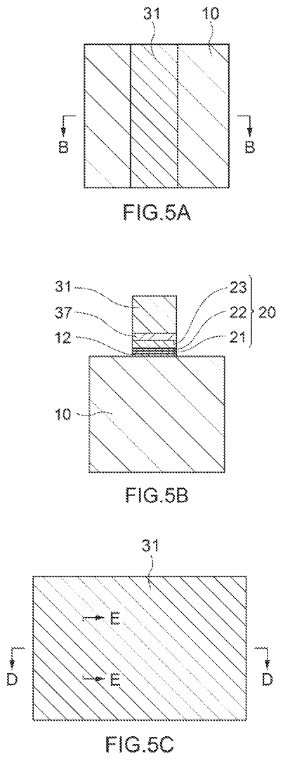

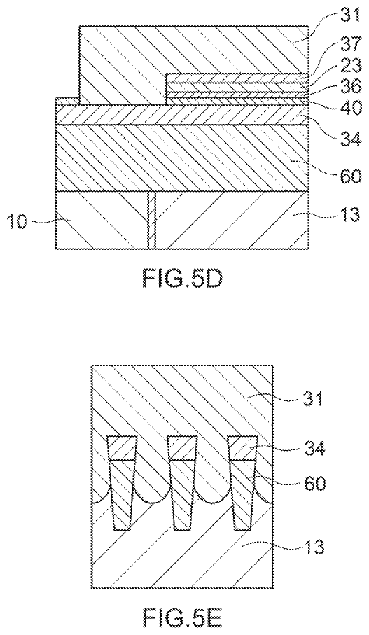

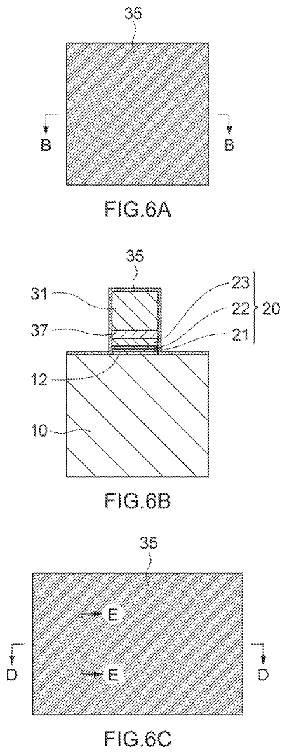

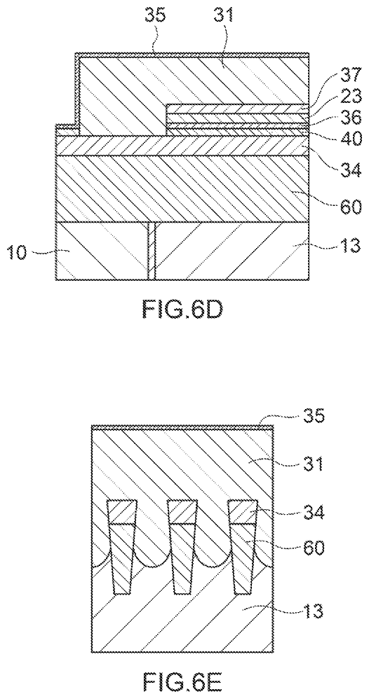

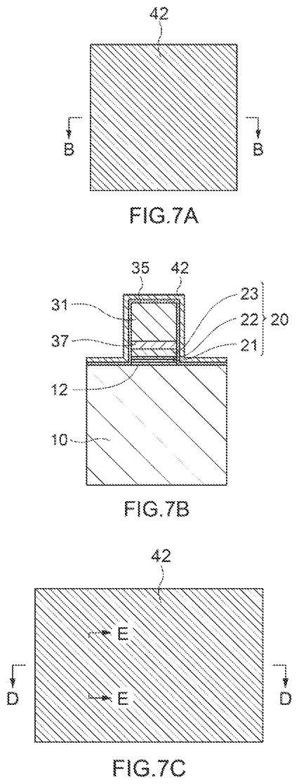

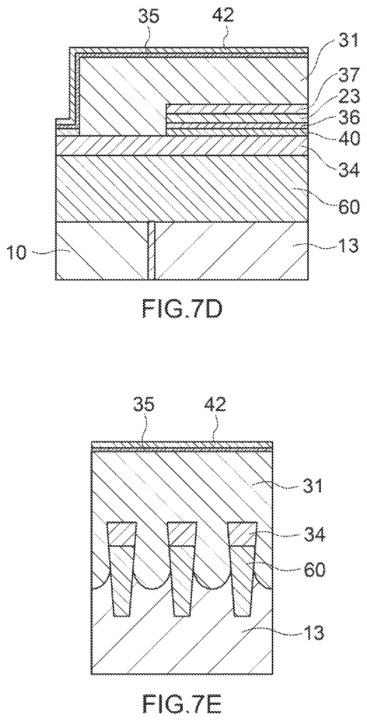

Next, after the resist 81 is removed, the thick silicon nitride film 31 is deposited on the whole surface as shown in FIGS. 4A to 4E. Accordingly, in the contact plug region, the upper section of each of the word lines 60 is brought to a state of being sandwiched by the silicon nitride film 31 in the Y direction. Next, as shown in FIGS. 5A to 5E, the silicon nitride film 31 formed in the peripheral circuit region is removed except for a portion to be left as the gate cap dielectric film 70 of the transistor 11, and the gate electrode 20 is patterned using the gate cap dielectric film 70 as a mask. The memory cell array region and the contact plug region are in a state of being covered with the silicon nitride film 31. Next, as shown in FIGS. 6A to 6E, the thin silicon nitride film 35 is deposited on the whole surface. Accordingly, the side surface of the gate electrode 20, and the top and side surfaces of the gate cap dielectric film 70 are covered with a spacer film including the silicon nitride film 35. As shown in FIG. 6D, the side surface of the silicon nitride film 31 located at a boundary between the peripheral circuit region and the contact plug region is also covered with the spacer film including the silicon nitride film 35. Furthermore, as shown in FIGS. 7A to 7E, the thin silicon oxide film 42 is deposited on the whole surface. Accordingly, the side surface of the gate electrode 20, and the top and side surfaces of the gate cap dielectric film 70 are covered with a spacer film including the silicon nitride film 35 and the silicon oxide film 42. As shown in FIG. 7D, the side surface of the silicon nitride film 31 located at the boundary between the peripheral circuit region and the contact plug region is also covered with the spacer film including the silicon nitride film 35 and the silicon oxide film 42.

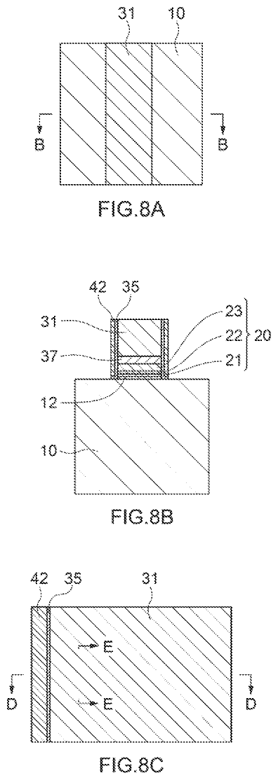

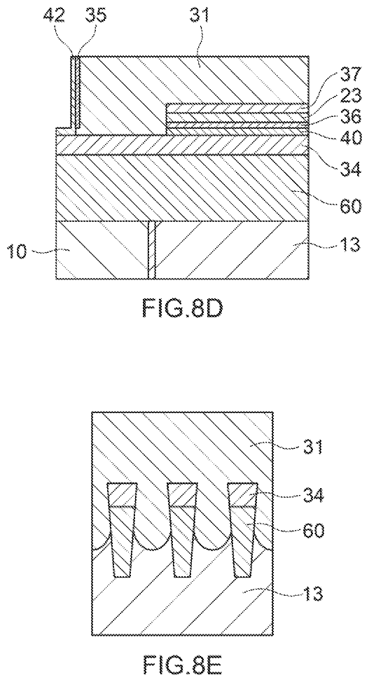

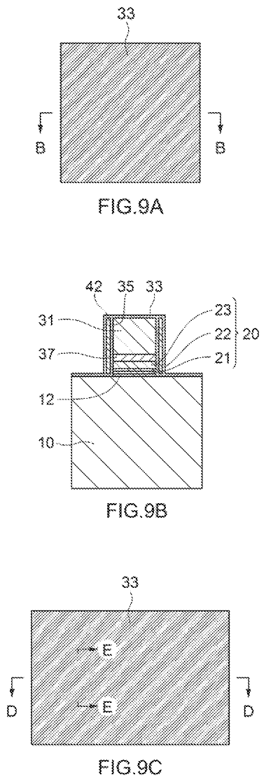

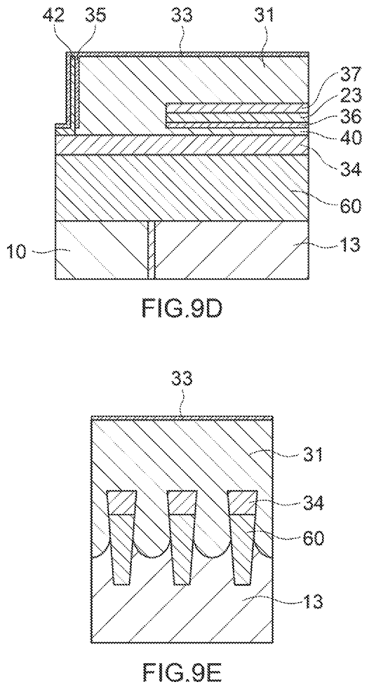

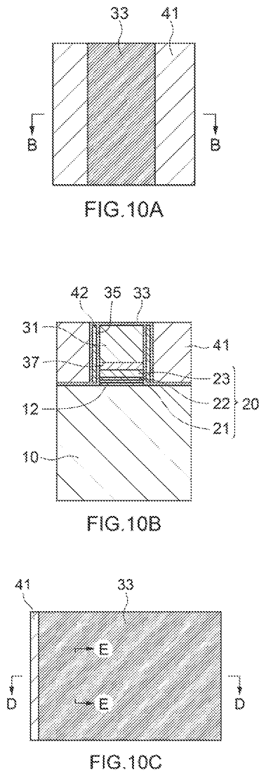

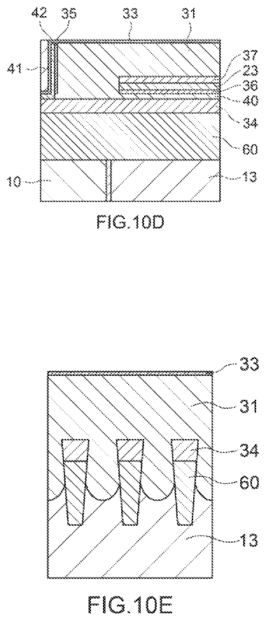

Next, as shown in FIGS. 8A to 8E, the silicon oxide film 42 and the silicon nitride film 35 are etched back to remove the silicon oxide film 42 and the silicon nitride film 35 formed on a horizontal plane. The spacer film covering the side surface of the gate cap dielectric film 70 remains. Next, as shown in FIGS. 9A to 9E, the thin silicon nitride film 33 is deposited on the whole surface. Accordingly, the side surface of the gate electrode 20, and the top and side surfaces of the gate cap dielectric film 70 are covered with a spacer film including the silicon nitride film 33. Furthermore, as illustrated in FIG. 9D, the side surface of the silicon nitride film 31 located at the boundary between the peripheral circuit region and the contact plug region is also covered with the spacer film including the silicon nitride film 33. Next, as shown in FIGS. 10A to 10E, after the thick silicon oxide film 41 is deposited on the whole surface, CMP (Chemical Mechanical Polishing) is performed for flattening using the silicon nitride film 33 as a stopper. Accordingly, a state in which the peripheral circuit region is covered with the silicon oxide film 41 and the memory cell array region and the contact plug region are covered with the silicon nitride films 31 and 33 is obtained, and the top surfaces of these regions become at substantially the same levels.

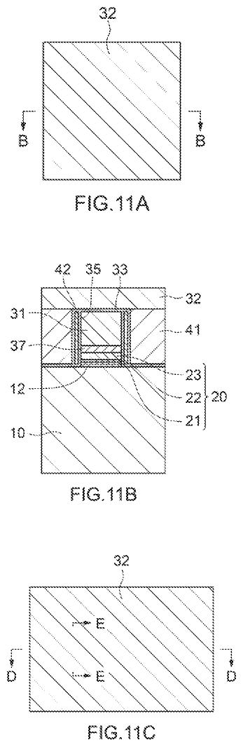

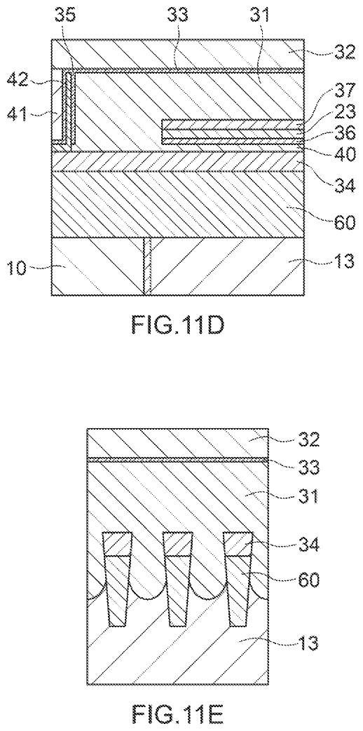

Next, as shown in FIGS. 11A to 11E, the thick silicon nitride film 32 is deposited on the whole surface. Accordingly, a state in which the silicon nitride film 32 is formed on the silicon oxide film 41 in the peripheral circuit region, and the silicon nitride film 32 is formed on the silicon nitride films 31 and 33 in the memory cell array region and the contact plug region is obtained. Particularly in the contact plug region, the silicon nitride films 34, 31, 33, and 32 are in a state of being stacked in this order on end portions of the word lines 60. That is, insulating films located on the word lines 60 all include a silicon nitride film. After a plurality of via holes reaching the word lines 60 are formed in the contact plug region, the contact plugs 52 including tungsten or the like are embedded in these via holes, whereby end portion regions of the word lines 60 are connected to associated ones of the contact plugs 52, respectively, as shown in FIGS. 1A to 1E. Interlayer dielectric films in which the via holes are formed all include a silicon nitride film. That is, since inner walls of the via holes are substantially formed of a silicon nitride film, the diameters of the via holes are less likely to be increased due to a chemical used in a cleaning process or the like. Accordingly, even when the pitch of the contact plugs 52 in the Y direction is narrow, a short circuit failure between adjacent ones of the contact plugs 52 is less likely to occur.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a semiconductor substrate in a first layer, the semiconductor substrate being divided, at least in part, into a memory cell array region, a peripheral circuit region and a contact plug region between the memory cell array region and the peripheral circuit region;
a plurality of word lines embedded in the semiconductor substrate, the plurality of word lines extending in parallel across only the memory cell array region and the contact plug region;
a first nitride film in a second layer above the first layer, the first nitride film covering the memory cell array region and the contact plug region of the semiconductor substrate;
a first oxide film in the second layer, the first oxide film covering the peripheral circuit region; and
a plurality of contact plugs in the first nitride film above the contact plug region of the semiconductor substrate to be connected to the plurality of word lines, respectively.

2. The apparatus of claim 1,
wherein the peripheral circuit region has a MOS transistor,
wherein the MOS transistor has a gate electrode, and
wherein a top surface of the gate electrode is covered with a gate cap insulator comprising a second nitride film arranged at substantially the same level as the first nitride film.

3. The apparatus of claim 2, wherein a side surface of the gate cap insulator is covered with the first oxide film.

4. The apparatus of claim 3, further comprising a third nitride film arranged above the first nitride film and the first oxide film.

5. The apparatus of claim 4, wherein the plurality of contact plugs penetrate through the first and third nitride films.

6. The apparatus of claim 5, further comprising a fourth nitride film arranged between the first and third nitride films.

7. The apparatus of claim 6, further comprising a plurality of nitride caps each between a corresponding one of the plurality of word lines and the first nitride film,
wherein each of the plurality of contact plugs penetrates through the first, third and fourth nitride films and a corresponding one of the plurality of nitride caps.

8. The apparatus of claim 7, further comprising a metal film arranged between the first nitride film and the plurality of nitride caps in the memory cell array region.

9. The apparatus of claim 8, wherein the gate electrode includes an additional metal film arranged at substantially the same level as the metal film.

10. The apparatus of claim 1, wherein a side surface of the first nitride film faces a side surface of the first oxide film at a boundary between the peripheral circuit region and the contact plug region.

11. The apparatus of claim 1, wherein each of the plurality of word lines has a lower section contacting a STI region and an upper section contacting the first nitride film in the contact plus region.

12. An apparatus comprising:
a plurality of word lines embedded in a semiconductor substrate, the plurality of word lines being arranged in a first direction, each of the plurality of word lines extending in a second direction;
a first nitride film covering the plurality of word lines; and
a plurality of contact plugs penetrating through the first nitride film so as to contact the plurality of word lines, respectively,
wherein each of the plurality of word lines has a lower section covered with a STI region in the first direction and an upper section covered with the first nitride film in the first direction.

13. The apparatus of claim 12, further comprising a MOS transistor having a gate electrode, wherein a top surface of the gate electrode is covered with a gate cap insulator constituted by the first nitride film.

14. The apparatus of claim 13, further comprising a second nitride film arranged above the first nitride film,
wherein the each of the plurality of contact plugs has a lower section contacting the upper section of an associated one of the plurality of word lines and surrounded by the first nitride film and an upper section surrounded by the second nitride film.

15. The apparatus of claim 14, wherein the lower section of each of the plurality of contact plugs is free from contacting with an oxide film.

16. The apparatus of claim 14, further comprising a third nitride film arranged between the first and second nitride films,
wherein the third nitride film is thinner than each of the first and second nitride films.

17. The apparatus of claim 16, wherein a side surface of the gate electrode and top and side surfaces of the gate cap insulator are covered with the third nitride film.

18. The apparatus of claim 17, further comprising a fourth nitride film arranged between the plurality of word lines and the first nitride film,
wherein the lower section of each of the plurality of contact plugs is covered with the fourth nitride film in the second direction.

19. The apparatus of claim 18, further comprising a metal film arranged between the first and fourth nitride films,
wherein the gate electrode includes the metal film.

20. A method comprising:
forming a plurality of word lines so as to be embedded in a semiconductor substrate;
forming a metal film covering the plurality of word lines with an insulating film interposed therebetween;
selectively removing the metal film covering an end portion of each of the plurality of word lines so as to expose the insulating film
forming a first nitride film after the removing;
forming a first oxide film after the forming the first nitride film;
forming a second nitride film covering the first nitride film and the first oxide film; and
forming a plurality of contact plugs penetrating through the first and second nitride film to contact the end portions of the plurality of word lines, respectively.

21. The method of claim 20, wherein each of the plurality of contact plugs is free from contacting with the first oxide film.
